(19) United States
(12) Patent Application Publication
(10) Pub. No.: US 2015/0255366 A1
(43) Pub. Date: Sep. 10, 2015

(54) EMBEDDED SYSTEM IN PACKAGE

(71) Applicant: Apple Inc., Cupertino, CA (US)

(72) Inventor: Chih-Ming Chung, Cupertino, CA (US)

(73) Assignee: Apple Inc., Cupertino, CA (US)

(21) Appl. No.: 14/199,400

(22) Filed: Mar. 6, 2014

(51) Int. Cl. H01L 23/367; H01L 23/31; H01L 25/00; H01L 23/29; H01L 23/00; H01L 25/065

(52) U.S. Cl. CPC H01L 23/3675; H01L 24/17; H01L 25/0657; H01L 25/50; H01L 24/11; H01L 24/81; H01L 23/293; H01L 23/3142; H01L 2224/1703; H01L 2225/06513; H01L 2225/06517; H01L 2225/06548; H01L 2225/06589; H01L 2224/1712; H01L 2224/16113; H01L 2224/16145; H01L 2224/16225

(57) ABSTRACT

In some embodiments, a system and/or method may include forming a semiconductor device package assembly. The method may include forming a substrate including a first surface and a second surface substantially opposite the first surface. The substrate may include an opening in the second surface. The first surface may include a first set of electrical conductors. The method may include positioning a first die in the opening. The first die may include a second set of electrical conductors. The method may include forming a third set of electrical conductors on a second die. The third set of conductors may include a first width and a first height. The method may include forming a fourth set of electrical conductors on the second die. The fourth set of conductors may include a second width and a second height. The second width may be less than the first width. The second height may be greater than the first height.

### BACKGROUND

1. Technical Field

The present invention relates to semiconductor packaging and methods for packaging semiconductor devices. More particularly, some embodiments disclosed herein relate to a SiP (system-in-package).

2. Description of the Related Art

Package-on-package (“PoP”) technology has become increasingly popular as the demand for lower cost, higher performance, increased integrated circuit density, and increased package density continues in the semiconductor industry. As the push for smaller and smaller packages increases, the integration of die and package (e.g., “pre-stacking” or the integration of system on a chip (“SoC”) technology with memory technology) allows for thinner packages. Such pre-stacking has become a critical component for thin and fine pitch PoP packages.

### SUMMARY

In some embodiments, an embedded PoP package includes a substrate with a first die embedded in the substrate forming a system-in-package. The SiP may include a second die coupled to the substrate and the first die. The second die may include two different sets of electrical conductors. One set of electrical conductors may function to electrically couple the second die to the substrate and through the substrate other systems exterior to the package. Another set of electrical conductors on the second die may electrically couple the second die to the first die. The second set of electrical conductors may have different dimensions than the first set. The second set of electrical conductors may have a smaller width and greater height in order to effectively electrically couple to the first die embedded in the substrate.

In some embodiments, a system and/or method may include forming a semiconductor device package assembly. The method may include forming a substrate including a first surface and a second surface substantially opposite the first surface. The substrate may include an opening in the second surface. The first surface may include a first set of electrical conductors. The method may include positioning a first die in the opening. The first die may include a second set of electrical conductors. The method may include forming a third set of electrical conductors on a second die. The third set of conductors may include a first width and a first height. The method may include forming a fourth set of electrical conductors on the second die. The fourth set of conductors may include a second width and a second height. The second width may be less than the first width. The second height may be greater than the first height.

In some embodiments, the method may include electrically coupling the second die to the first die using the fourth set of electrical conductors and the second set of electrical conductors. In some embodiments, the method may include electrically coupling the second die to the second surface using the third set of electrical conductors. In some embodiments, the method may include electrically coupling the third set of electrical conductors to at least some of the first set of electrical conductors.

### BRIEF DESCRIPTION OF THE DRAWINGS

The following detailed description makes reference to the accompanying drawings, which are now briefly described.

FIG. 1 depicts an embodiment of flow chart representing a method of forming at least a portion of a SiP.

FIG. 2 depicts an embodiment of a semiconductor device package assembly. At least some of the electrical conductors are not depicted for the sake of clarity.

FIG. 3 depicts an embodiment of a semiconductor device package assembly including a fifth set of electrical conductors. At least some of the electrical conductors are not depicted for the sake of clarity.

FIG. 4 depicts an embodiment of a semiconductor device package assembly including a cover. At least some of the electrical conductors are not depicted for the sake of clarity.

FIG. 5 depicts an embodiment of a top perspective view of a SiP mounted on a motherboard.

FIGS. 6-8 depict an embodiment of several stages of a method of producing a SiP including installing a first die in a substrate.

FIGS. 9A-D depict an embodiment of several stages of a method of producing a SiP including producing a second die with at least two different sets of electrical conductors.

FIGS. 10-11 depict an embodiment of several stages of a method of producing a SiP including installing a second die on a substrate.

FIGS. 12-14 depict an embodiment of several stages of a method of producing a SiP including installing electrical conductors on a substrate for producing a PoP.

FIGS. 15-16 depict an embodiment of several stages of a method of producing a SiP including a cover.

FIGS. 17A-G depict an embodiment of several stages of a method of producing a SiP including a cover and micro vias electrically connecting a first die to a first set of electrical conductors. At least some of the electrical conductors are not depicted for the sake of clarity.

Specific embodiments are shown by way of example in the drawings and will be described herein in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

The headings used herein are for organizational purposes only and are not meant to be used to limit the scope of the description. As used throughout this application, the word “may” is used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third die electrically connected to the module substrate” does not preclude scenarios in which a “fourth die electrically connected to the module substrate” is connected prior to the third die, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. §112, paragraph six, interpretation for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

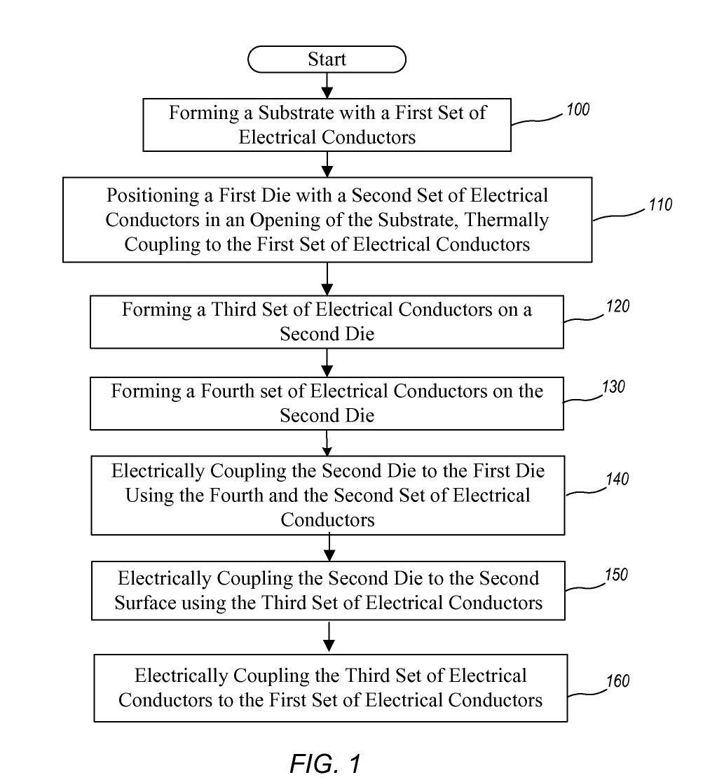

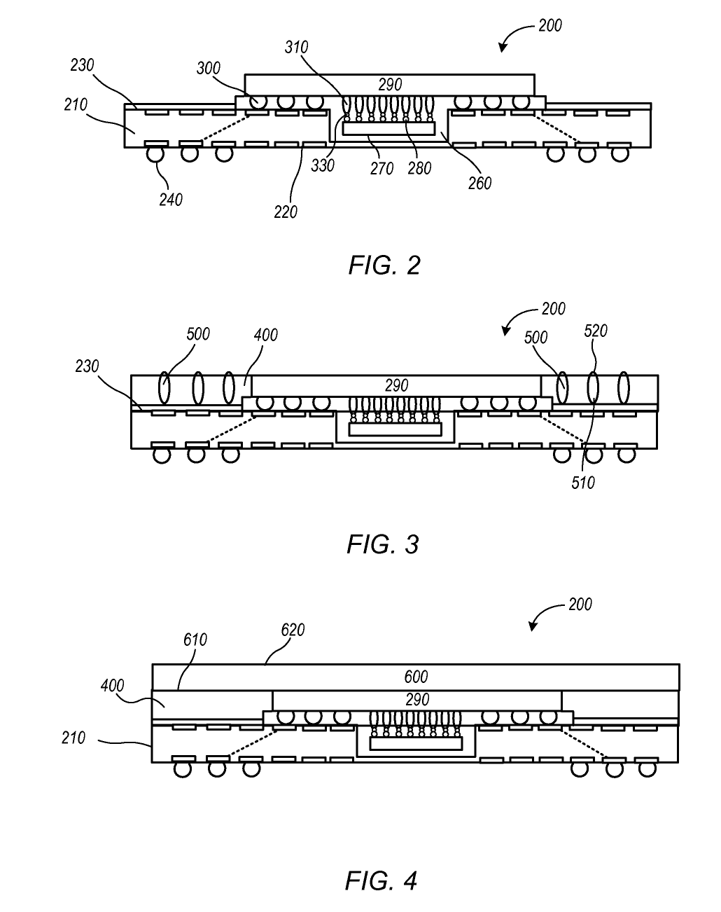

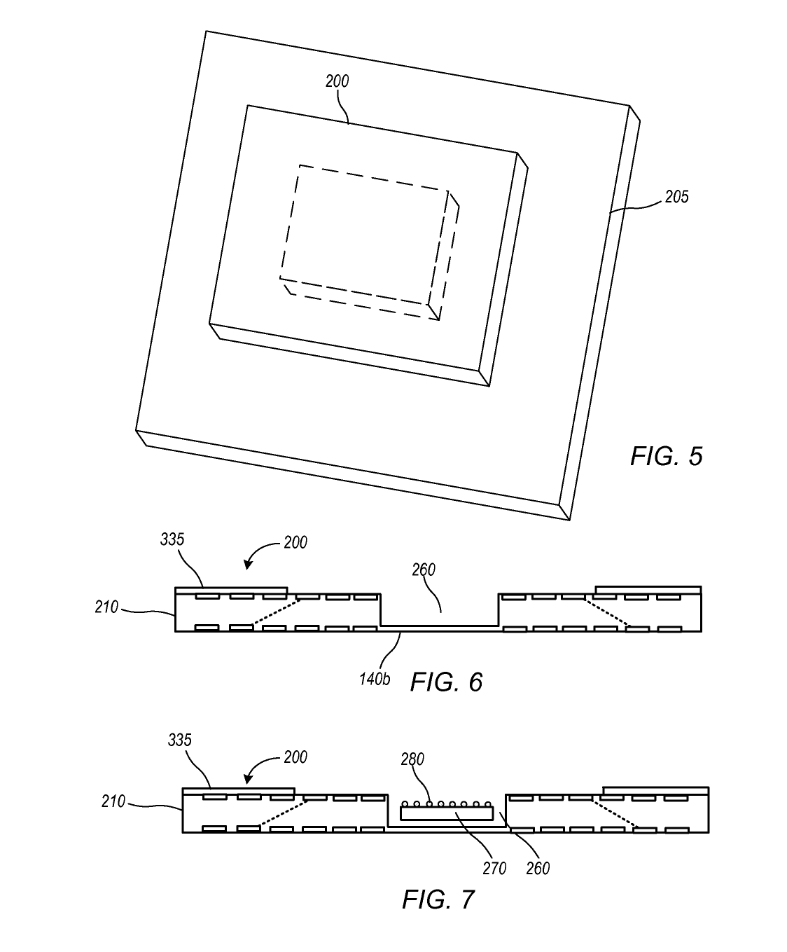

In some embodiments, a system and/or method may include forming a semiconductor device package assembly. FIG. 1 depicts an embodiment of flow chart representing a method of forming at least a portion of a SiP. FIGS. 2-4 depict an embodiment of semiconductor device package assembly 200 as might be formed using the method described in FIG. 1. Semiconductor device package assemblies discussed herein may be used in a number of electronic devices including personal computers, cell phones, etc. FIG. 5 depicts an embodiment of a top perspective view of semiconductor device package assembly 200 mounted on a motherboard 205. In other embodiments, semiconductor device package assembly 200 may be coupled to another component (e.g., an SOC or other integrated circuit chip in a separate package) using package-on-package configurations.

The method may include forming 100 a substrate including a first surface and a second surface substantially opposite the first surface. The substrate may include an opening in the second surface. The first surface may include a first set of electrical conductors. The method may include positioning 110 a first die in the opening. The first die may include a second set of electrical conductors.

FIG. 2 depicts an embodiment of semiconductor device package assembly 200 as might be formed using the method described in FIG. 1. At least some of the electrical conductors are not depicted for the sake of clarity. In some embodiments, semiconductor device package assembly 200 may include substrate 210. The substrate may include first surface 220 and second surface 230 substantially opposite of the first surface. The substrate may include first set of electrical conductors 240 coupled to the first surface. The first set of electrical conductors may function to electrically connect the semiconductor device package assembly, and more specifically the substrate, to other electronic devices and/or assemblies.

In some embodiments, the substrate may include opening 260. Opening 260 may extend down into the substrate. The opening may not extend through the substrate. The semiconductor device package assembly may include first die 270 positioned in the opening. The first die may be positioned below the second surface of the substrate. The first die may include second set of electrical conductors 280. Embedding the first die in the substrate may allow for a thinner overall package. FIGS. 6-8 depict an embodiment of several stages of a method of producing semiconductor device package assembly 200 including installing the first die in the opening of the substrate (after solder resist or dielectric material 335 has been applied to the second surface of the substrate (e.g., as depicted in FIG. 6)). FIG. 8 depicts non-conducting paste 285 which is applied over the first die in the opening in the substrate.

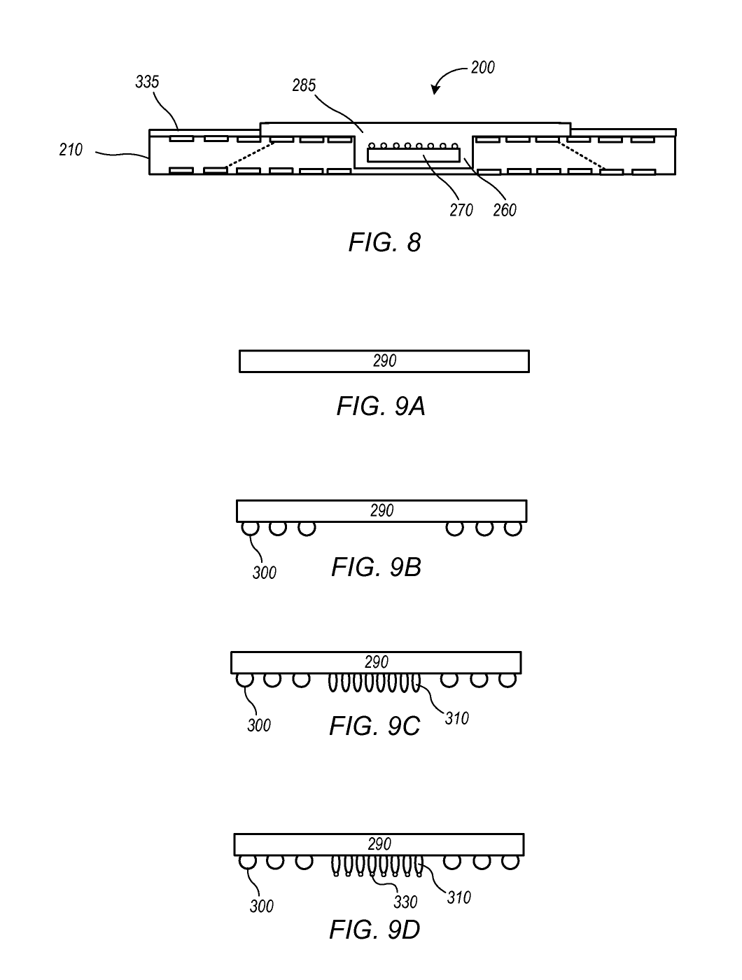

In some embodiments, the semiconductor device package assembly may include second die 290. FIGS. 9A-D depict an embodiment of several stages of a method of producing second die 290 with at least two different sets of electrical conductors.

Second die 290 may include third set of electrical conductors 300. In some embodiments, the method may include forming 120 third set of electrical conductors 300 on second die 290 (e.g., as depicted in FIG. 9B). The third set of conductors may include a first width and a first height. Second die 290 may include fourth set of electrical conductors 310. The method may include forming 130 fourth set of electrical conductors 310 on second die 290 (e.g., as depicted in FIG. 9C). The fourth set of conductors may include a second width and a second height. The second width may be less than the first width. The second height may be greater than the first height. In some embodiments, the fourth set may be coupled to the second set using couplers 330 (e.g. solder balls as from a ball grid array (e.g., as depicted in FIG. 9D)).

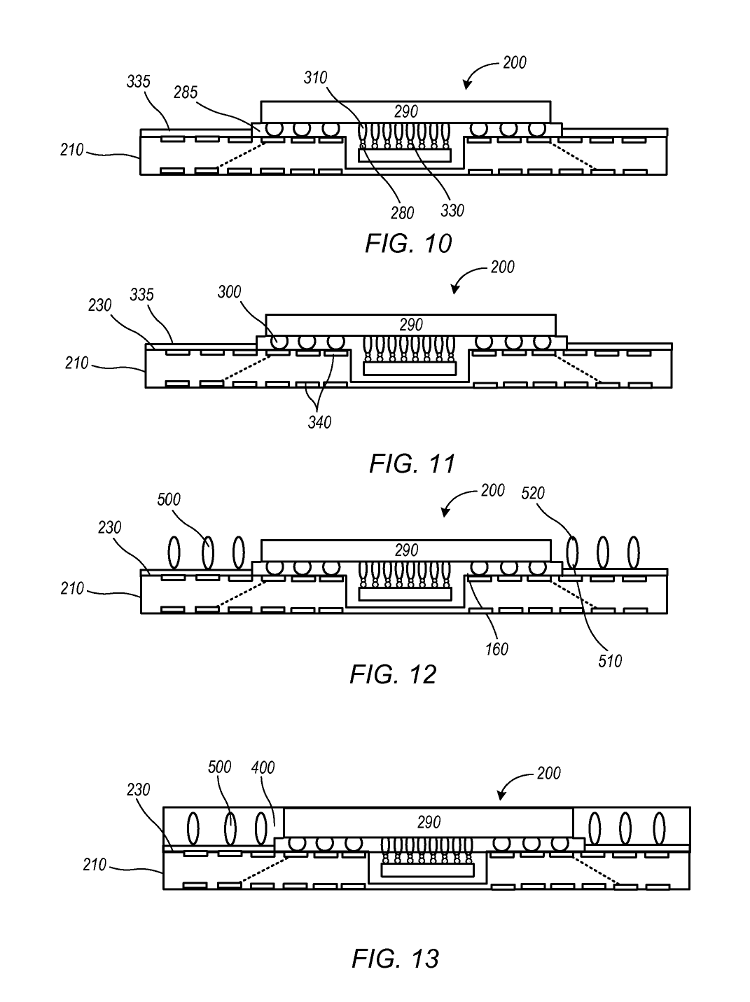

In some embodiments, the method may include electrically coupling 140 the second die to the first die using the fourth set of electrical conductors and the second set of electrical conductors. FIGS. 10-11 depict an embodiment of several stages of a method of producing semiconductor device package assembly 200 including installing second die 290 on substrate 210. The second die may be positioned in the non-conducting paste such that the electrical conductors are in alignment (e.g., as depicted in FIG. 10). The assembly may be exposed to pressure and/or heat such that couplers 330 may melt to better electrically connect the fourth set of electrical conductors and the second set of electrical conductors. The non-conducting paste may ensure that there is no cross-coupling between the electrical conductors. The different terminal width and height of the fourth set of electrical conductors may allow for the die to die interconnection with the first die. Die to die interconnection may provide exceptional routing feasibility especially for fine trace width/spacing which allows optimization of circuit layouts and improve electrical performance (e.g., higher bandwidth data transmission between the first and second die due to short I/O distances).

In some embodiments, the method may include electrically coupling 150 the second die to the second surface using the third set of electrical conductors. In some embodiments, the method may include electrically coupling 160 the third set of electrical conductors to at least some of the first set of electrical conductors. The substrate may include electrical conductors 340 which allow for electrical communication through the substrate (e.g., between the third set and the first set of electrical conductors).

In some embodiments, the method may include encapsulating the second surface of the substrate and at least a portion of the second die using an electrically insulating material. In some embodiments, a semiconductor device package assembly may include electrically insulating material 400 covering at least a portion of second surface 230 and second die 290 (e.g., as depicted in FIGS. 3-4). In some embodiments, the electrically insulating material may encapsulate an upper portion of the semiconductor device package assembly. The electrically insulating material may include a dielectric polymer. In some embodiments, the method may include inhibiting deformation of the semiconductor device package assembly using the dielectric polymer.

Deformation of the semiconductor device package assembly and/or at least a portion of said assembly is commonly referred to as warpage. Excessive warpage may lead to solder ball bridging, solder slumping, head and pillow defects, or open joints. More than 90% of the defects that occur during package-on-package assembly are the result of package warpage. Minimizing warpage is a tradeoff between materials, temperature control, and time. The extent and degree of warpage is increasing as substrates become thinner. Mismatches in coefficient of thermal expansions between parts of a package assembly may result in increased warpage.

Thermal expansion is the tendency of matter to change in volume in response to change in temperature. The degree of expansion divided by the change in temperature is called the material's coefficient of thermal expansion (CTE) and generally varies with temperature. Reducing the CTE of the various components of a package assembly is generally advantageous in reducing deformation of the package assembly. Substrates have been developed with lower CTEs and as such a dielectric polymer with reduced CTEs would be advantageous. In some embodiments, the dielectric polymer may include a coefficient of thermal expansion of between about 5 to about 15 ppm/° C. Such a CTE may be compared to typical solder masks having a CTE of about 50 to about 60 ppm/° C.

Young's modulus, also known as the tensile modulus, is a measure of the stiffness of an elastic material and is a quantity used to characterize materials. It is defined as the ratio of the uniaxial stress over the uniaxial strain in the range of stress in which Hooke's law holds. The Young's modulus calculates the change in the dimension of a bar made of an isotropic elastic material under tensile or compressive loads. For instance, it predicts how much a material sample extends under tension or shortens under compression. Young's modulus is used in order to predict the deflection that will occur in a statically determinate beam when a load is applied at a point in between the beam's supports. Some calculations also require the use of other material properties, such as the shear modulus, density, or Poisson's ratio. Increasing the modulus of the various components of a package assembly is generally advantageous in reducing deformation of the package assembly when exposed to stress during use. In some embodiments, the dielectric polymer may include a modulus of between about 15 to about 25 Gpa. Such a modulus may be compared to typical solder masks having a modulus of about <5 Gpa.

In some embodiments, the dielectric polymer may include a polymer (e.g., epoxy) based resin and a filler. The dielectric polymer may include a polymer (e.g., epoxy) based resin and a filler, wherein the filler comprises glass fibers.

In some embodiments, the method may include forming fifth set of electrical conductors 500 on second surface 230 of substrate 210. FIGS. 12-14 depict an embodiment of several stages of a method of producing semiconductor device package assembly 200 including installing electrical conductors on a substrate for producing a PoP. FIG. 3 depicts an embodiment of semiconductor device package assembly 200 including fifth set of electrical conductors 500. At least some of the electrical conductors are not depicted for the sake of clarity. The fifth set of electrical conductors may include first end 510 coupled to the second surface of the substrate and second end 520 substantially opposite the first end. FIG. 12 depicts an embodiment of fifth set of electrical conductors 500 coupled to semiconductor device package assembly 200. The fifth set of electrical conductors may electrically connect, during use, to at least some of the first set of electrical conductors through the substrate.

In some embodiments, semiconductor device package assembly 200 may be covered with electrically insulating material 400, covering at least a portion of second surface 230, at least a portion of second die 290, and fifth set of electrical conductors 500 (e.g., as depicted in FIG. 13).

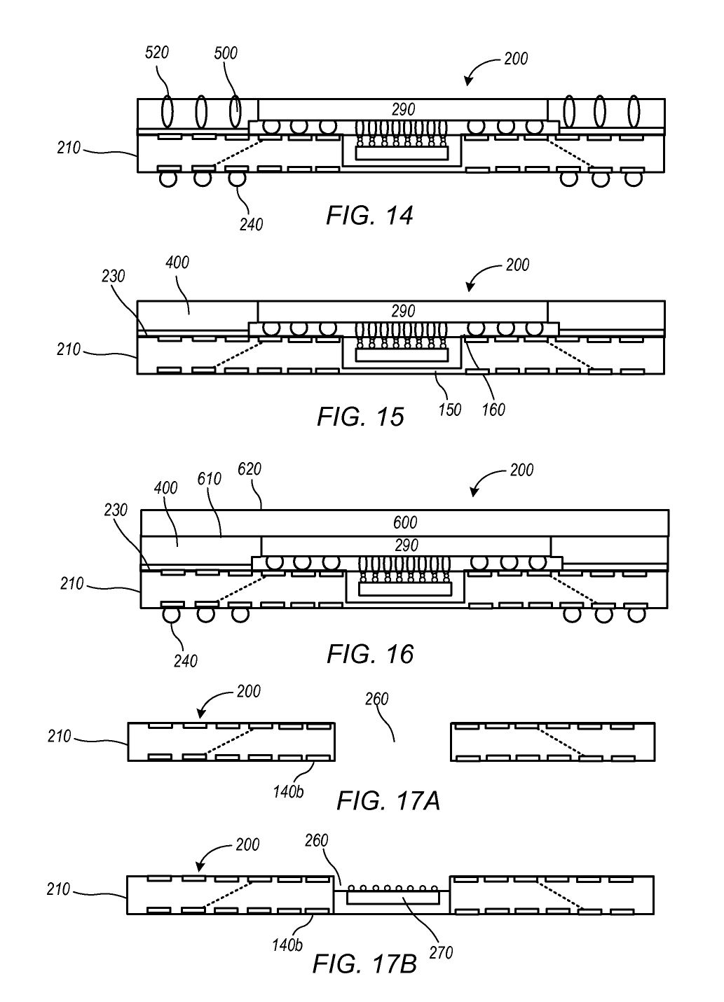

In some embodiments, the method may include exposing at least a portion of the second end of the fifth set of electrical conductors by removing at least some of the electrically insulating material. The method may include exposing at least a portion of the second end of the fifth set of electrical conductors using a laser drill or ablation. FIG. 14 depicts an embodiment of semiconductor device package assembly 200 after exposing at least a portion of second end 520 of fifth set of electrical conductors 500.

In some embodiments, the method may include coupling cover 600 to electrically insulating material 400. FIG. 4 depicts an embodiment of semiconductor device package 200 assembly including cover 600. At least some of the electrical conductors are not depicted for the sake of clarity. In some embodiments, semiconductor device package assembly 200 may be covered with electrically insulating material 400, covering at least a portion of second surface 230 and at least a portion of second die 290 (e.g., as depicted in FIGS. 15). The method may include coupling first side 610 of a cover to the electrically insulating material (e.g., as depicted in FIGS. 16). The cover may include second side 620 substantially opposite the first side. The method may include transferring heat from the substrate and/or the second die through the cover from the first side to the second side. Effectively the cover may function to dissipate heat generated by the semiconductor device package assembly during use extending life of the package assembly and/or inhibiting deformation of the package assembly.

The cover may function as a heat exchanger that moves heat between a heat source, and a secondary heat exchanger whose surface area and geometry are more favorable than the source. Such a spreader is most often simply a plate made of copper, which has a high thermal conductivity.

Heat spreaders transfer heat from electronic components to passive or active heat sinks Typically they are used to cool chips in personal computers, laptops, notebooks, cell phones, and other electronic devices. Heat spreaders are used in critical locations for more efficient heat removal. Heat spreaders may be used to reduce electrical component hot spots, such that the component's lifetime is increased and the component's performance is improved.

In some embodiments, the cover may provide structural stability to the package assembly. The cover may be formed from, for example, copper, aluminum alloys, high thermal conductivity ceramics, composite graphite, etc.

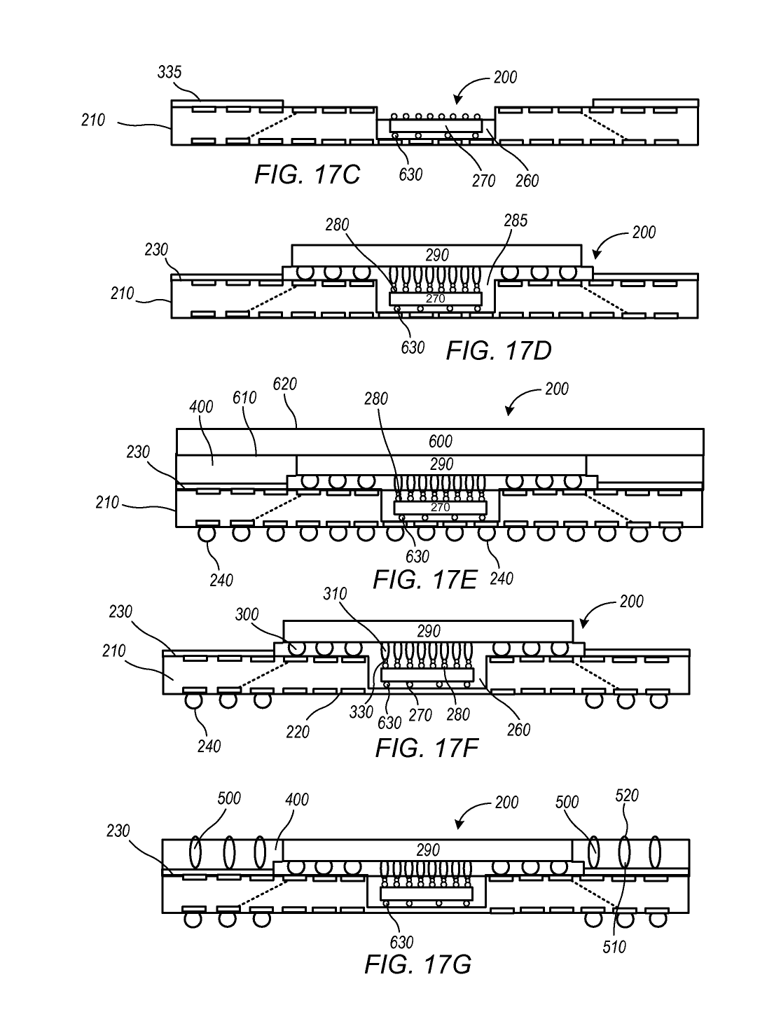

FIGS. 17A-G depict an embodiment of several stages of a method of producing a cross-section of a SiP including a cover and micro vias electrically connecting a first die to a first set of electrical conductors. At least some of the electrical conductors are not depicted for the sake of clarity. FIG. 17A depicts a cross-section of the substrate 210 wherein the opening 260 has been created as part of a method of creating a SIP. The method may include positioning a first die 270 in the opening and integrate into substrate 210 manufacture/embedded processes (e.g., as depicted in FIG. 17B). Micro vias 630 may be installed electrically coupling the first die 270 (e.g., as depicted in FIG. 17C). Solder resist or dielectric material 335 may be applied to the second surface of the substrate and/or the upper exposed surface of the second die (e.g., as depicted in FIG. 17C). The second die 290 may be installed such that the second die is electrically coupled to the first die 270 (e.g., as depicted in FIG. 17D). In some embodiments, a semiconductor device package assembly may include electrically insulating material 400 covering at least a portion of second surface 230 and second die 290 (e.g., as depicted in FIG. 17E). In some embodiments, the electrically insulating material may encapsulate an upper portion of the semiconductor device package assembly. In some embodiments, the method may include coupling cover 600 to electrically insulating material 400. FIG. 17E depicts an embodiment of semiconductor device package 200 assembly including cover 600.

In some embodiments, first die 270 may include a sixth set of electrical conductors 630 (e.g., as depicted in FIGS. 17C-G). FIG. 17E depicts an embodiment of a semiconductor device package assembly including a cover and micro vias 630 electrically connecting a first die to a first set of electrical conductors. At least some of the electrical conductors are not depicted for the sake of clarity. The sixth set of electrical conductors may be positioned on an opposing side of the first die relative to the second set of electrical conductors 280. The sixth set of electrical conductors may include micro vias which electrically couple the first die to first set of electrical conductors 240. The sixth set of electrical conductors may also thermally couple the first die to the first set of electrical conductors directly increasing the thermal efficiency of the package. FIG. 17F depicts an embodiment of an uncovered semiconductor device package assembly 200 including a sixth set of electrical conductors 630 (e.g., micro vias). FIG. 17G depicts an embodiment of semiconductor device package assembly 200 including fifth set of electrical conductors 500 and a sixth set of electrical conductors 630 (e.g., micro vias).

What is claimed is:

1. A method for forming a semiconductor device package assembly, comprising:
forming a substrate comprising a first surface and a second surface substantially opposite the first surface, wherein the substrate comprises an opening in the second surface, and wherein the first surface comprises a first set of electrical conductors;
positioning a first die in the opening, wherein the first die comprises a second set of electrical conductors;
forming a third set of electrical conductors on a second die, wherein the third set of conductors comprise a first width and a first height;
forming a fourth set of electrical conductors on the second die, wherein the fourth set of conductors comprise a second width and a second height, wherein the second width is less than the first width and the second height is greater than the first height;
electrically coupling the second die to the first die using the fourth set of electrical conductors and the second set of electrical conductors;
electrically coupling the second die to the second surface using the third set of electrical conductors; and
electrically coupling the third set of electrical conductors to at least some of the first set of electrical conductors.

2. The method of claim 1, further comprising electrically coupling a sixth set of electrical conductors to at least some of the first set of electrical conductors, wherein the first die comprises the sixth set of electrical conductors.

3. The method of claim 1, further comprising encapsulating the second surface of the substrate and at least a portion of the second die using an electrically insulating material, wherein the electrically insulating material comprises a dielectric polymer.

4. The method of claim 2, further comprising inhibiting deformation of the semiconductor device package assembly using the dielectric polymer.

5. The method of claim 2, further comprising forming a fifth set of electrical conductors on the second surface of the substrate, wherein the fifth set of electrical conductors comprise a first end coupled to the second surface of the substrate and a second end substantially opposite the first end, and wherein the fifth set of electrical conductors electrically connect, during use, to at least some of the first set of electrical conductors.

6. The method of claim 5, further comprising exposing at least a portion of the second end of the fifth set of electrical conductors.

7. The method of claim 5, further comprising exposing at least a portion of the second end of the fifth set of electrical conductors using a laser drill or ablation.

8. The method of claim 2, further comprising coupling a cover to the electrically insulating material.

9. The method of claim 2, further comprising:
coupling a first side of a cover to the electrically insulating material, wherein the cover comprises a second side substantially opposite the first side; and
transferring heat from the substrate and/or the second die through the cover from the first side to the second side.

10. A method for forming a semiconductor device, comprising:
forming a first set of electrical conductors on a first die, wherein the first set of conductors comprise a first width and a first height; and
forming a second set of electrical conductors on the first die, wherein the second set of conductors comprise a second width and a second height, wherein the second width is less than the first width and the second height is greater than the first height.

11. The method of claim 10, further comprising electrically coupling the first die to a second die comprising a third set of electrical conductors using the second set of electrical conductors and the third set of electrical conductors.

12. The method of claim 11, further comprising:
forming a substrate comprising a first surface and a second surface substantially opposite the first surface, wherein the substrate comprises an opening in the second surface, and wherein the first surface comprises a fourth set of electrical conductors; and
positioning the second die in the opening.

13. The method of claim 12, further comprising electrically coupling the first die to the second surface using the first set of electrical conductors.

14. The method of claim 12, further comprising electrically coupling the first set of electrical conductors to at least some of the fourth set of electrical conductors.

15. The method of claim 12, further comprising further comprising forming a fifth set of electrical conductors on the second surface of the substrate, wherein the fifth set of electrical conductors comprise a first end coupled to the second surface of the substrate and a second end substantially opposite the first end, and wherein the fifth set of electrical conductors electrically connect, during use, to at least some of the fourth set of electrical conductors.

16. A semiconductor device package assembly, comprising:
a substrate including a first surface, a second surface substantially opposite of the first surface, and a first set of electrical conductors coupled to the first surface configured to electrically connect the substrate, wherein the second surface comprises an opening in the second surface;
a first die positioned in the opening in the second surface of the substrate, wherein the first die comprises a second set of electrical conductors; and
a second die comprising a third set of electrical conductors and a fourth set of electrical conductors, wherein the third set of conductors comprise a first width and a first height, wherein the fourth set of conductors comprise a second width and a second height, wherein the second width is less than the first width and the second height is greater than the first height, wherein the third set of electrical conductors electrically couple the second die to the second surface of the substrate, wherein the third set of electrical conductors electrically couple the second die to at least some of the first set of electrical conductors, and wherein the fourth set of electrical conductors electrically couple the second die to the first die using the second set of electrical conductors.

17. The assembly of claim 16, further comprising an electrically insulating material covering at least a portion of the second surface and the die, wherein the electrically insulating material comprises a dielectric polymer.

18. The assembly of claim 17, wherein the dielectric polymer is configured to function as a solder mask and/or an encapsulating composition.

19. The assembly of claim 17, further comprising a first side of a cover coupled to the electrically insulating material, wherein the cover comprises a second side substantially opposite the first side, and wherein the cover is configured to transfer heat from the first substrate and/or the first die through the cover from the first side to the second side.

20. The assembly of claim 17, further comprising a fifth set of electrical conductors positioned on the second surface of the first substrate, wherein the fifth set of electrical conductors comprise a first end coupled to the second surface of the first substrate and a second end substantially opposite the first end, and wherein the fifth set of electrical conductors electrically connect, during use, to at least some of the first set of electrical conductors.
